(19) United States
(12) Patent Application Publication
(10) Pub. No.: US 2024/0313711 A1
(43) Pub. Date: Sep. 19, 2024

(54) DISTORTION CORRECTION FOR FAST SUPPLY VOLTAGE CHANGES IN POWER AMPLIFIER

(71) Applicant: Qorvo US, Inc., Greensboro, NC (US)

(72) Inventors: George Maxim, Saratoga, CA (US); Nadim Khlat, Cugnaux (FR); Chong Woo, Fremont, CA (US); Baker Scott, San Jose, CA (US)

(21) Appl. No.: 18/413,290

(22) Filed: Jan. 16, 2024

Related U.S. Application Data
(60) Provisional application No. 63/452,199, filed on Mar. 15, 2023.

(51) Int. Cl. H03F 1/32; H04B 1/04

(52) U.S. Cl. CPC H03F 1/3282; H04B 1/0475; H03F 2200/102; H03F 2200/105; H03F 2201/3233; H04B 2001/0425

(57) ABSTRACT

Distortion correction for fast supply voltage changes in a power amplifier is disclosed. In one aspect, analog predistortion in the power amplifier to maintain linearity of the power amplifier is based on a supply voltage, thereby avoiding a need to write into registers. Further, the supply voltage with its changes may be used to set the predistortion levels both for amplitude and phase. By using the supply voltage, long signals writing to registers in the power amplifier or power management circuit may be avoided, resulting in faster application of predistortion. The faster application of the predistortion works nicely with symbol or even sub-symbol adjustments to the supply voltage resulting in greater efficiency in the power amplifier.

### PRIORITY APPLICATION

This application claims the benefit of U.S. Provisional Patent Application Ser. No. 63/452,199, filed on Mar. 15, 2023, entitled, “DISTORTION CORRECTION FOR FAST SUPPLY VOLTAGE CHANGES IN POWER AMPLIFIER,” the disclosure of which is hereby incorporated herein by reference in its entirety.

### BACKGROUND

### I. Field of the Disclosure

The technology of the disclosure relates generally to direct current-to-direct current (DC-DC) converters that may be used as average power tracking (APT) or envelope tracking (ET) circuits in a power amplifier circuit.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to reduce power consumption. One way that power consumption has been reduced is to make power amplifiers in transmission circuits more efficient by changing a supply voltage for the power amplifier dynamically based on changes in the signal. Such adjustments may be made through an average power tracking (APT) or envelope tracking (ET) circuit. As the pace with which such adjustments are made increases to the symbol and even sub-symbol time scale, there is room for innovation in addressing complications caused by such fast changes.

### SUMMARY

Aspects disclosed in the detailed description include systems and methods for distortion correction for fast voltage supply changes in a power amplifier. In particular, exemplary aspects of the present disclosure provide analog predistortion in the power amplifier to maintain linearity of the power amplifier, thereby avoiding a need to write into registers. Further, the supply voltage with its changes may be used to set the predistortion levels both for amplitude and phase. By using the supply voltage, long signals writing to registers in the power amplifier or power management circuit may be avoided, resulting in faster application of predistortion. The faster application of the predistortion works nicely with symbol or even sub-symbol adjustments to the supply voltage resulting in greater efficiency in the power amplifier.

In this regard, in one aspect, a power amplifier circuit is disclosed. The power amplifier circuit comprises an amplifier stage configured to receive a transmit signal and amplify the transmit signal, a supply voltage input configured to receive a signal containing information relating to a supply voltage being provided to the power amplifier circuit, and a bias circuit coupled to the amplifier stage and configured to provide a bias signal to the amplifier stage based at least in part on the signal. The power amplifier circuit also comprises an analog predistortion (APD) circuit configured to predistort the transmit signal based at least in part on the signal.

In another aspect, a transmit circuit is disclosed. The transmit circuit comprises a power management circuit configured to receive a signal from a baseband processor relating to a power level for a transmit signal and output a supply voltage signal. The transmit circuit also comprises a power amplifier circuit that comprises an amplifier stage configured to receive the transmit signal and amplify the transmit signal and receive the supply voltage signal. The power amplifier circuit also comprises a bias circuit coupled to the amplifier stage and configured to provide a bias signal to the amplifier stage based at least in part on the supply voltage signal and an analog predistortion (APD) circuit configured to predistort the transmit signal based at least in part on the supply voltage signal.

### BRIEF DESCRIPTION OF THE DRAWINGS

FIG. 1 is a block diagram of an exemplary mobile terminal with a transceiver system that may include transmit circuitry having one or more power amplifiers therein;

FIG. 2 is a block diagram providing additional details about the transmit circuitry of FIG. 1;

FIG. 3 is a block diagram highlighting a communication bus that couples parts of the transmit circuitry of FIG. 2;

FIG. 4A is a gain versus power graph showing what happens to the gain when supply voltage changes as a function of a power management circuit;

FIG. 4B is a phase versus power graph showing what happens to the phase when supply voltage changes as a function of a power management circuit;

FIG. 5 is a signal timing diagram for signals that are used in the transmit circuitry of FIG. 1;

FIG. 6 is a block diagram of transmit circuitry according to the present disclosure, where analog predistortion circuits use supply voltage information from a power management circuit to effectuate fast changes to predistortion values in response to fast changes in the supply voltage;

FIG. 7 is a block diagram of an alternate aspect of the transmit circuitry of FIG. 6 with circuitry to address latency that may exist between different signal paths;

FIG. 8 is a hybrid block and circuit diagram of part of the transmit circuitry of FIG. 6 with some details about possible analog predistortion circuits;

FIG. 9 is a block diagram showing additional details about the circuitry to address latency between different signal paths;

FIG. 10 is a hybrid block and circuit diagram of parts of the transmit circuitry with additional details about how the predistortion works with a bias circuit to provide predistortion to a signal for a power amplifier; and

FIG. 11 is a block diagram of an alternate transmit circuit that uses envelope tracking in place of average power tracking in the power management circuit.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for distortion correction for fast voltage supply changes in a power amplifier. In particular, exemplary aspects of the present disclosure provide analog predistortion in the power amplifier to maintain linearity of the power amplifier, thereby avoiding a need to write into registers. Further, the supply voltage with its changes may be used to set the predistortion levels both for amplitude and phase. By using the supply voltage, long signals writing to registers in the power amplifier or power management circuit may be avoided, resulting in faster application of predistortion. The faster application of the predistortion works nicely with symbol or even sub-symbol adjustments to the supply voltage resulting in greater efficiency in the power amplifier.

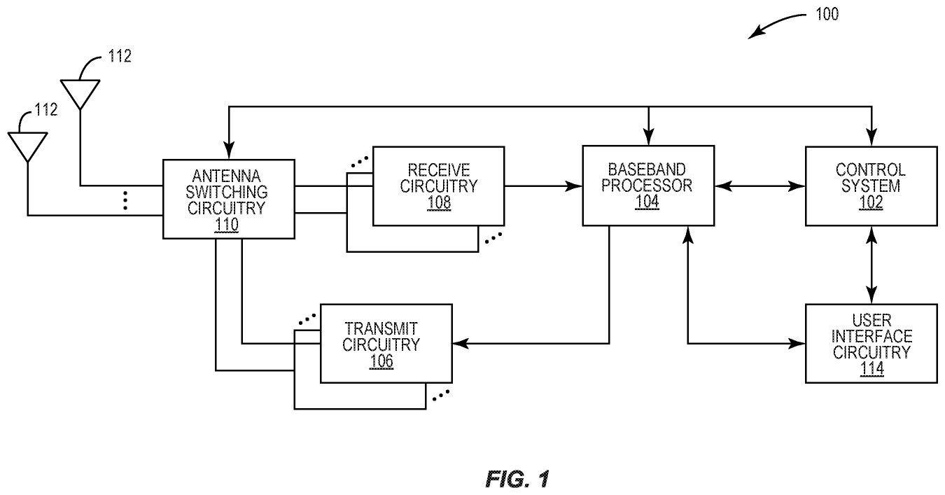

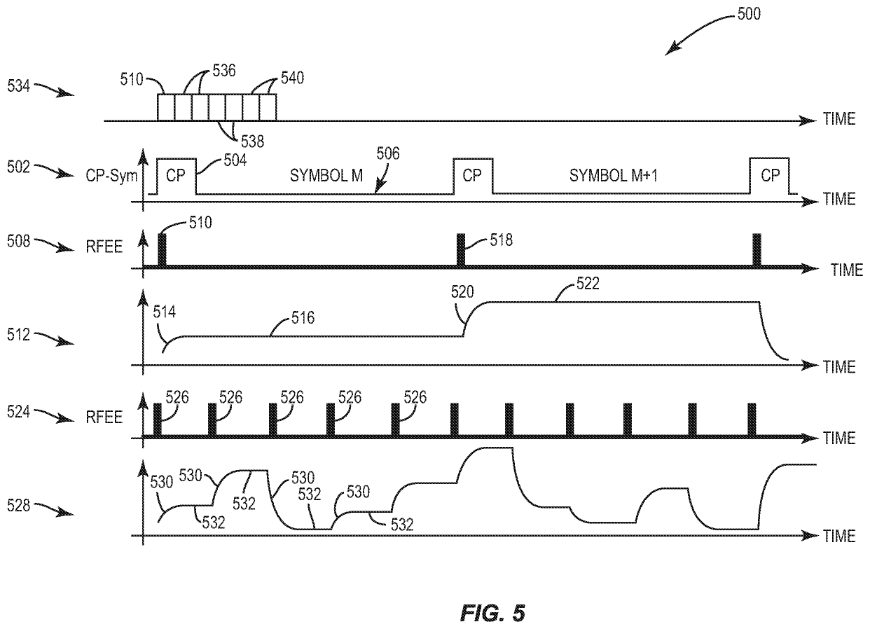

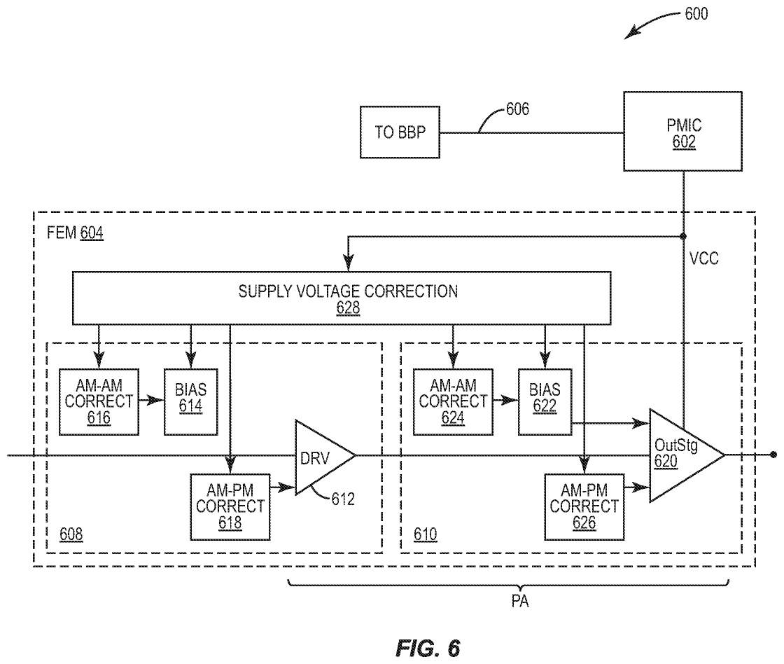

Before addressing specific aspects of the present disclosure, an overview of a mobile terminal having transmit circuitry that may contain a power management circuit is provided with reference to FIGS. 1-4B. Challenges that may arise from traditional circuitry are highlighted in FIG. 5. A discussion of exemplary aspects begins below with reference to FIG. 6.

In this regard, FIG. 1 illustrates a mobile terminal 100, which may be a cellular phone, smartphone, smartwatch, tablet, computer, navigation device, access points, or similar wireless communication device that support wireless communication, such as cellular, wireless local area network (WLAN), Bluetooth, and near field communications. The mobile terminal 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA) or an application-specific integrated circuit (ASIC), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter of the receive circuitry 108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 40 through the antenna switching circuitry 110 to the antennas 112. The multiple antennas 112 and the replicated transmit and receive circuitries 106, 108 may provide spatial diversity. Modulation and processing details will be understood by those skilled in the art.

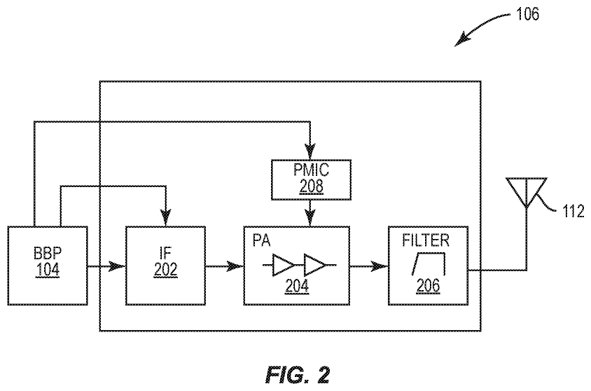

More specifically, and as better illustrated in FIG. 2, the transmit circuitry 106 may include an intermediate frequency (IF) circuit 202 that performs the upconverts an initial baseband signal from the baseband processor 104 to an IF and/or to a radio frequency (RF). The upconverted signal is then amplified by a power amplifier circuit 204 and filtered by a filter 206 before radiating from the antenna 112. A power management circuit 208 may be implemented as a separate integrated circuit and thus may be referred to as a power management integrated circuit (PMIC) and may be instantiated as an average power tracking (APT) circuit or an envelope tracking (ET) circuit, for example.

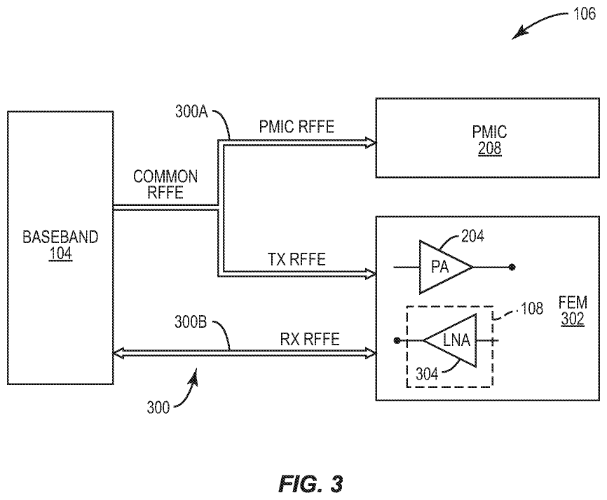

In practice, the power management circuit 208 may be used to change supply voltage (e.g., Vcc) for power amplifier stages in the power amplifier circuit 204. Changes to the supply voltage may be made to improve the efficiency of the power amplifier. That is, by keeping the supply voltage proximate to a required output power, less power is used, as is well understood. As explained in greater detail below, the speed at which the supply voltage is being changed is increasing. This increase in the speed at which the supply voltage is being changed creates challenges, as further explained with reference to FIGS. 3-5.

In particular, FIG. 3 illustrates a communication bus 300 that may exist between elements of the transmit circuitry 106. Specifically, the communication bus 300 may be an RF front-end (RFFE) bus that complies with the standard published by MIPI. The RFFE bus is a two-wire bus that operates at relatively low frequencies (at least compared to transmit RF ranges). There may actually be two RFFE buses 300A, 300B, where the first RFFE bus 300A is a transmit RFFE bus, and the second RFFE bus 300B is a receive RFFE bus. The transmit RFFE bus 300A may provide signals between the BBP 104 and the PMIC 208 as well as transmit elements of a front-end module (FEM) 302, such as the power amplifier circuit 204. The FEM 302 may also include elements of the receive circuitry 108, such as a low noise amplifier 304. The RFFE bus 300B may communicate with elements of the receive circuitry 108 in the FEM 302. Relevantly, the RFFE bus 300A does not allow for simultaneous writing to both the FEM 302 and the PMIC 208.

It is generally known that power amplifiers may not behave linearly across all input powers. Such non-linearities may be addressed by applying changes to bias signals provided to the power amplifier as well as through application of digital predistortion (DPD) in the baseband processor 104 and/or application of analog predistortion (APD) in the FEM 302.

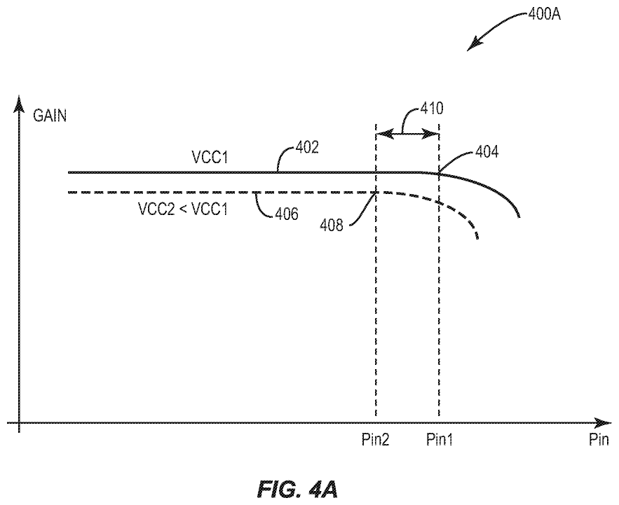

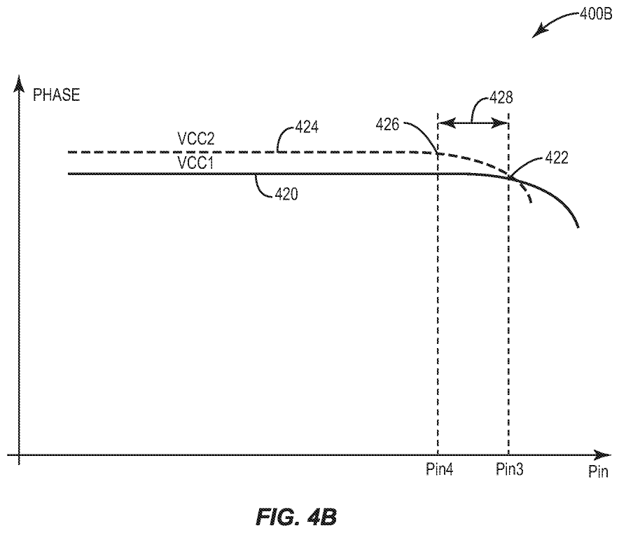

A further complication arises when the supply voltage changes. Such supply voltage change may cause the nature of non-linear behavior to change also, as better seen in FIGS. 4A and 4B, where input power (Pin) is plotted against gain and phase in graphs 400A and 400B, respectively. In graph 400A, at a first supply voltage (shown by line 402), compression begins at point 404 (i.e., Pin1). In contrast, at a second supply voltage (shown by line 406) less than the first supply voltage, compression may begin at point 408 (i.e., Pin2). The difference 410 means that a static APD that addresses gain (such gain APD being referred to as amplitude modulation (AM)-to-AM or AM-AM APD) may not correct the distortion and/or may make the distortion worse. Further, in general, it is not only the position of the compression point that changes but also the slope of the gain compression that can change with the supply voltage. It should be noted that compression is used as an example, and instead, the non-linearity may be expansion.

Likewise, graph 400B at a first supply voltage (shown by line 420), phase distortion begins at point 422 (i.e., Pin3). In contrast, at a second supply voltage (shown by line 424) greater than the first supply voltage, phase distortion may begin at point 426 (i.e., Pin4). The difference 428 means that a static APD (such phase APD being referred to as AM-to-phase modulation (PM) or AM-PM APD) may not correct the distortion and/or may make the distortion worse.

As wireless modulation frequencies trend higher, there has been a concurrent trend in changing power levels more frequently. Specifically, symbol-to-symbol power levels may vary, and there are emerging trends to have sub-symbol power variation. This puts pressure on the PMIC 208 to change the power levels with greater speed to maintain efficiencies.

Traditionally, supply voltage changes are indicated to the PMIC 208 from the BBP 104 through the RFFE bus 300A. FIG. 5 illustrates a signal versus time graph 500 to illustrate some of the challenges of using the RFFE bus 300A to communicate changes to the PMIC 208 as well as the FEM 302. Line 502 shows the general shape of a symbol with a cyclic prefix (CP) 504 followed by a symbol 506. For a 30 kilohertz (kHz) orthogonal frequency division multiplexed (OFDM) signal, the CP time is 2.3 microseconds. The CP 504 is more resistant to distortion. Accordingly, the BBP 104 may write to a register in the PMIC 208 during the CP 504, as shown in line 508, with RFFE burst 510 being an 8-bit write signal across the RFFE bus 300A. This RFFE burst 510 takes twenty-four clock cycles and thus may be almost two microseconds. Writing the new supply voltage to the PMIC 208 corresponds to a change in the supply voltage, but such a change is not instantaneous. Thus, as shown in line 512, the supply voltage may have an initial settling slope 514, followed by a steady state 516. Subsequent changes, such as those triggered by burst 518, may also have a settling slope 520 and a subsequent steady state 522.

For sub-symbol power level changes, the RFFE bursts may come more frequently, as shown in line 524 having uniform or non-uniform RFFE bursts 526 during a symbol 506. In such use, as illustrated by line 528, the supply voltage may move up and down with corresponding settling times 530 and relatively brief steady states 532. Given these supply voltage changes, there may be a need to make corresponding changes in the APD, as discussed above, with reference to FIGS. 4A and 4B.

One approach would be to have the BBP 104 write to bias registers and/or APD registers in the power amplifier circuit 204. However, as shown by line 534, the RFFE burst 510 takes up part of the CP 504, writing to the bias registers takes another set of clock cycles 536, writing to the AM-AM correction registers takes another set of clock cycles 538, and writing to the AM-PM correction registers takes still another set of clock cycles 540. Given the inability to have parallel writing instructions on the RFFE bus 300A and the general speed of the RFFE bus 300A, the sum of 510, 536, 538, and 540 is greater than the length of the CP 504, and thus the APD corrections may occur during the transmission of the symbol 506. Having these APD corrections occur during the symbol 506 is inefficient and may degrade performance. Such concerns are only exacerbated in sub-symbol tracking.

While one solution would be to add one or more parallel RFFE buses that allow parallel writing to the various registers in FEM 302, this approach is commercially impractical as the extra pins and conductors consume space and cost more. Thus, there is an opportunity for innovation in solving the concerns about such fast-tracking situations.

Exemplary aspects of the present disclosure allow APD circuitry to track fast-changing supply voltages without requiring direct communication from the BBP. Specifically, exemplary aspects of the present disclosure contemplate using supply voltage information from the PMIC to set APD and bias levels so that such corrections can be made promptly, even when the supply voltage is rapidly changing.

In this regard, FIG. 6 illustrates transmit circuitry 600 (analogous to transmit circuitry 106 of FIG. 1) that implements this solution. Specifically, the transmit circuitry 600 includes a PMIC 602 and a FEM 604. The PMIC 602 may be an envelope tracking (ET) circuit or an average power tracking (APT) circuit and may receive a signal from a BBP 104 through a communication bus 606. The communication bus 606 may be an RFFE bus and may provide an instruction to write to a register in the PMIC 602, where the register controls a supply voltage signal (VCC) generated by the PMIC 602.

The FEM 604 may include a driver amplifier stage 608 and an output amplifier stage 610. The driver amplifier stage 608 may include a driver amplifier 612 with a corresponding driver bias circuit 614. Additionally, an AM-AM APD circuit 616 may be coupled to the driver bias circuit 614, and an AM-PM APD circuit 618 may be coupled to the driver amplifier 612. Other arrangements may also exist. For example, the AM-PM APD circuit 618 may also be coupled to the bias circuit 614. The output amplifier 610 is similar and includes an output amplifier 620 with a corresponding output bias circuit 622. Additionally, an output AM-AM APD circuitry 624 may be coupled to the output bias circuit 622, and an AM-PM APD circuit 626 may be coupled to the output amplifier 620. Again, other arrangements may also exist.

The supply voltage signal is provided to the output amplifier 620 and may modulate an output of the output amplifier 620 as is known. Additionally, the supply voltage signal may be provided to a supply voltage correction circuit 628 through a supply voltage input on the FEM 604. The supply voltage correction circuit 628 uses the supply voltage signal to generate control signals that are provided to bias circuits 614, 622, AM-AM APD circuits 616, 624, and AM-PM APD circuits 618, 626. The receiving circuits adjust their output signals based on the signals from the supply voltage correction circuit 628 so as to provide the appropriate bias and APD corrections.

The transmit circuit 600 contemplates using the supply voltage signal directly to inform the supply voltage correction circuit 628. However, in some cases, the supply voltage line has a significant delay. This delay may cause the APD correction and/or the bias correction to misalign with changes in the signal being amplified and/or with the arrival of the supply voltage change at the output amplifier 620. Accordingly, alternate aspects of the present disclosure use an analog signal derived from the supply voltage with some time advance to compensate for latency in the supply voltage path.

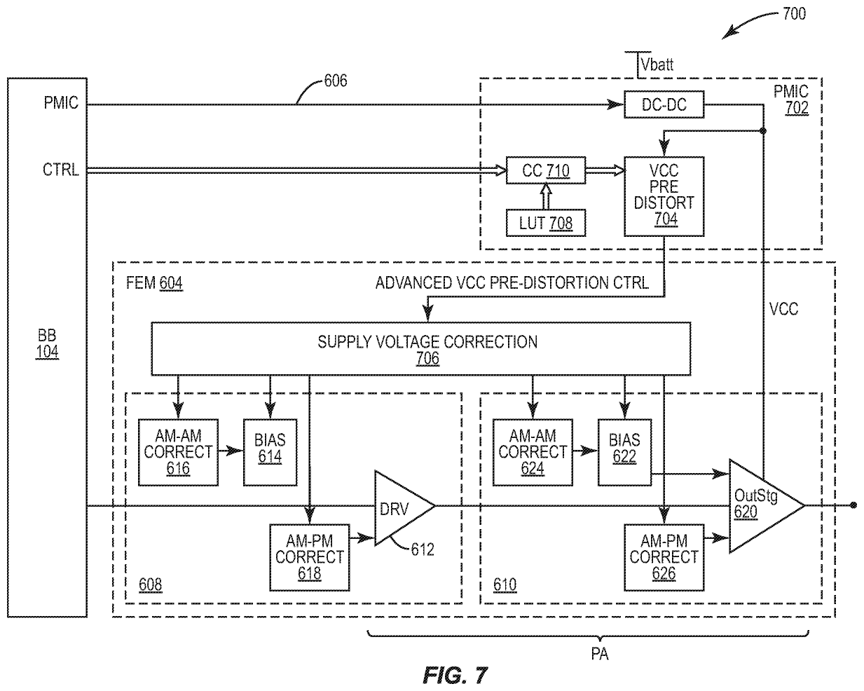

FIG. 7 illustrates this alternate aspect in transmit circuitry 700. Much of transmit circuitry 700 is similar to transmit circuitry 600, but the PMIC 702 may include a predistortion circuit 704 that acts to predistort the supply voltage signal before providing the same to the supply voltage correction circuit 706. The predistortion circuit 704 may rely on information in a look-up table (LUT) 708. The values in the LUT 708 may also be based on operating modes (e.g., low power mode, mid-power mode, high power mode). Also, different values can be used for specific ranges of supply voltage. Note that the PMIC 702 may have a control circuit 710 that provides information from the LUT 708 to the predistortion circuit 704. The control circuit 710 may use the supply voltage value to use the LUT 708, or there may be a separate signal from the BBP 104.

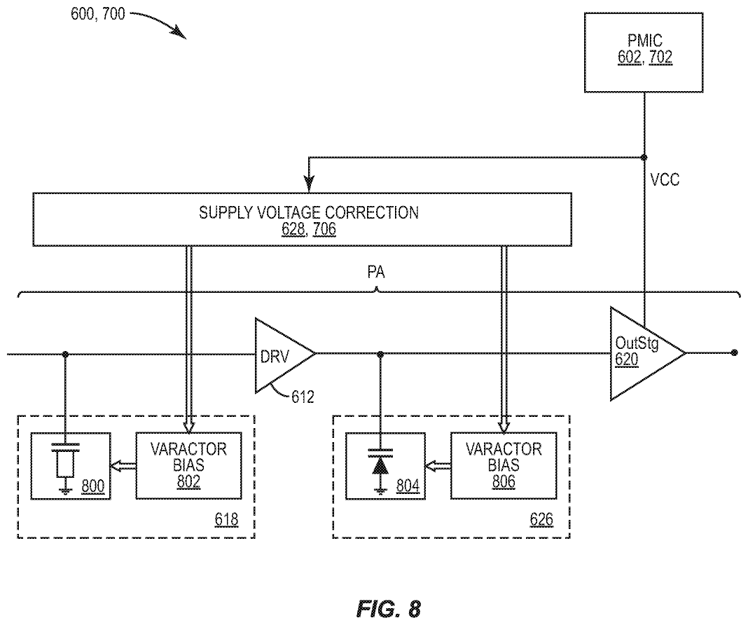

FIG. 8 illustrates additional details about the AM-PM APD circuits 618 and 628. It should be appreciated that only one AM-PM APD circuit may be present without departing from the present disclosure. Likewise, for multi-stage power amplifiers, it is generally easier to correct the phase distortion in the stage that creates the distortion. Thus, the AM-PM APD circuit may be positioned to have maximum efficaciousness. Phase distortion may be corrected with controlled phase shifting, and many types of phase shifters may be used. In one exemplary aspect, a varactor-based phase shifter is contemplated. Such a varactor may be a diode varactor or a field effect transistor (FET) varactor. As illustrated in FIG. 8, the AM-PM APD circuit 618 includes a FET varactor 800 with a varactor bias 802. The AM-PM APD circuit 626 includes a diode varactor 804 with a varactor bias 806. It should be appreciated that FET varactors (inversion or accumulation type) are generally only available in complementary metal oxide semiconductor (CMOS) and BiCMOS processes. In contrast, diode varactors may be available in MOS processes and bipolar processes.

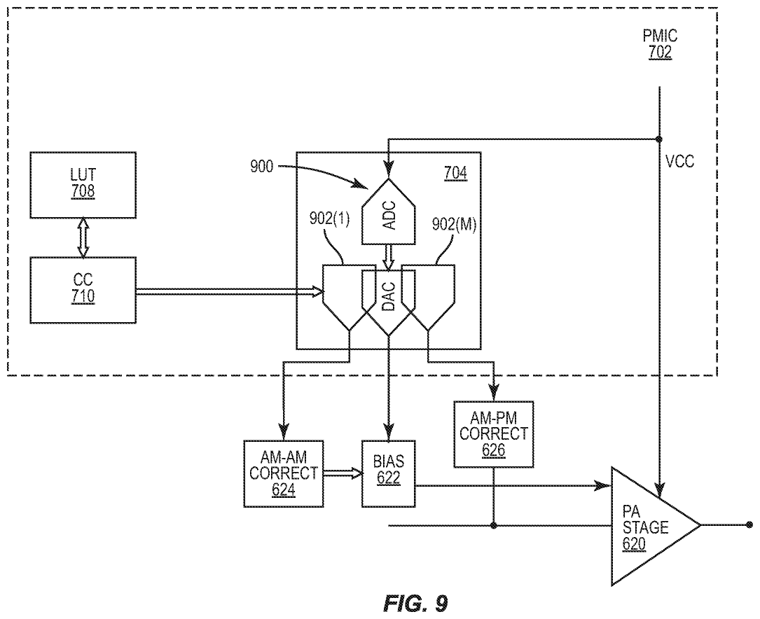

FIG. 9 illustrates some additional details about one exemplary aspect of the predistortion circuit 704. Specifically, the predistortion circuit 704 may include an analog-to-digital converter (ADC) 900 that converts the supply voltage to a digital value and one or more digital-to-analog converters (DAC) 902(1)-902(M) that are adjusted based on the input from the control circuit 710. This structure is offered because bipolar processes such as gallium arsenide (GaAs) do not support digital circuits, while mixed-signal circuits such as DACs and ADCs are costly to implement. Thus, for bipolar power amplifiers, the APD circuitry and any corresponding supply voltage correction are optimally implemented in pure analog fashion. However, pure analog solutions are static and not amenable to adjustment post-fabrication. Thus, the use of a digital control through the use of mixed signals, such as shown in FIG. 9, provides an acceptable compromise.

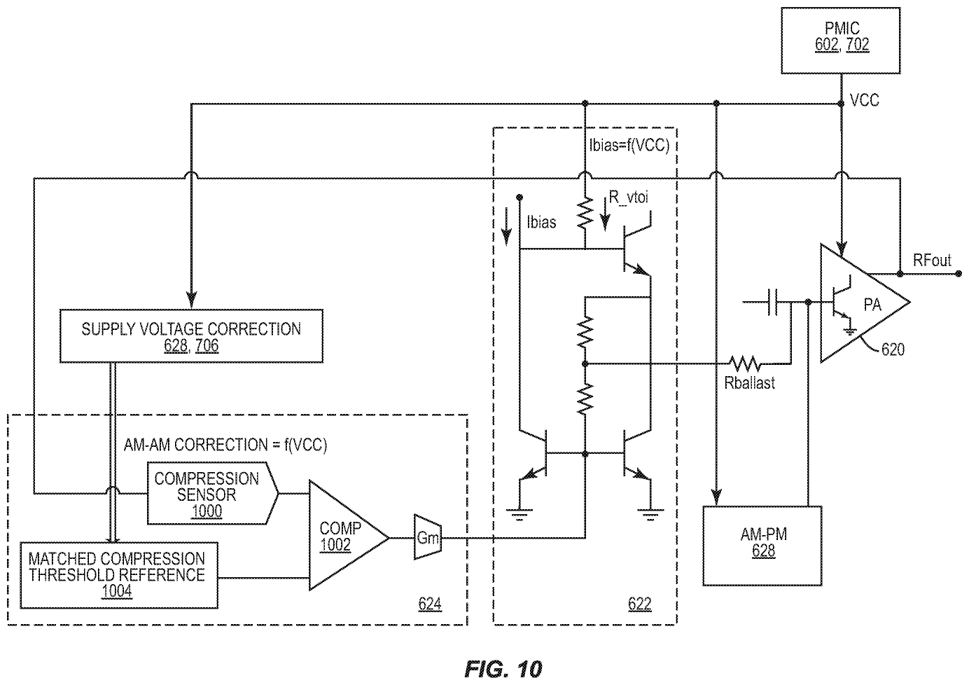

Additional details about the AM-AM APD circuit and bias circuit are provided in FIG. 10. In particular, the bias circuit 622 may include a current mirror that provides a bias signal through a ballast resistor to the output amplifier 620. The output amplifier 620 may be a bipolar transistor. The AM-AM APD circuit 624 may include a compression sensor 1000. The compression sensor 1000 provides a signal to a comparator 1002 that compares this value to a value from a threshold reference 1004 to provide a transconductance value to the bias circuit 622.

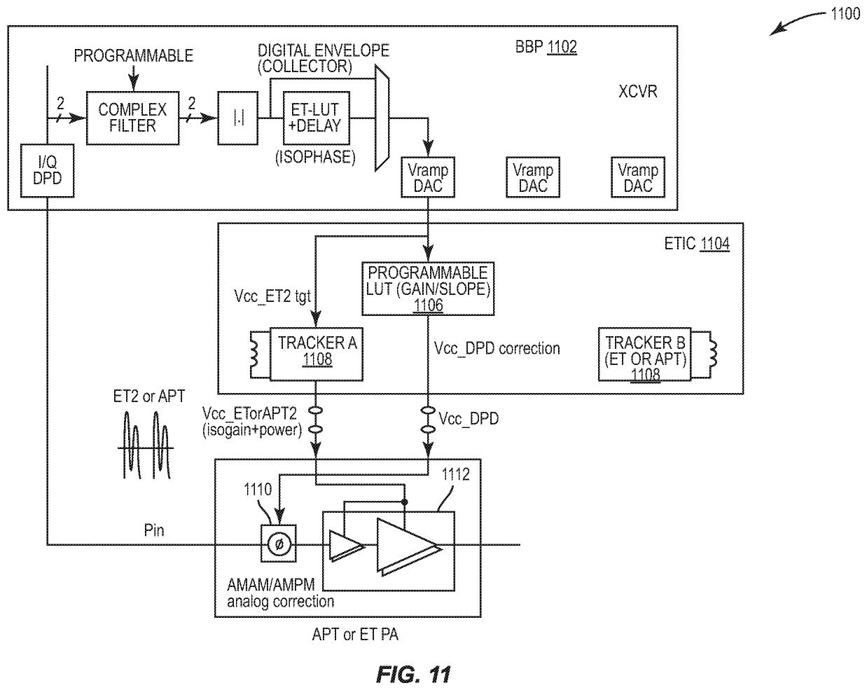

Most of the above discussion has focused on an APT-based PMIC, but as noted above, this present disclosure is not so limited and may be applied to an ET PMIC. FIG. 11 provides more detail on an ET environment. Specifically, transmit circuitry 1100 works with a BBP 1102. The transmit circuitry 1100 includes an ET circuit 1104 with a programmable LUT 1106 and a tracker circuitry 1108. The LUT 1106 may provide a corrected supply voltage signal to APD circuits 1110 associated with the amplifier chain 1112, while the tracker circuitry 1108 sets the supply voltage for the amplifier chain 1112.

The systems and methods for distortion correction for fast voltage supply changes in a power amplifier according to aspects disclosed herein may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power amplifier circuit comprising:
an amplifier stage configured to receive a transmit signal and amplify the transmit signal;
a supply voltage input configured to receive a signal containing information relating to a supply voltage being provided to the power amplifier circuit;
a bias circuit coupled to the amplifier stage and configured to provide a bias signal to the amplifier stage based at least in part on the signal;
an analog predistortion (APD) circuit configured to predistort the transmit signal based at least in part on the signal.

2. The power amplifier circuit of claim 1, wherein the APD circuit comprises an amplitude modulation (AM)-to-AM (AM-AM) predistortion circuit.

3. The power amplifier circuit of claim 1, wherein the APD circuit comprises an amplitude modulation (AM)-to-phase modulation (PM) (AM-PM) predistortion circuit.

4. The power amplifier circuit of claim 1, further comprising a supply voltage correction circuit configured to receive the signal and provide control signals to the bias circuit and the APD circuit based on the signal.

5. The power amplifier circuit of claim 1, wherein the amplifier stage comprises an output amplifier stage.

6. The power amplifier circuit of claim 1, wherein the amplifier stage comprises a driver amplifier stage.

7. The power amplifier circuit of claim 1, wherein the signal comprises the supply voltage.

8. The power amplifier circuit of claim 1, wherein the signal comprises a predistorted version of the supply voltage.

9. The power amplifier circuit of claim 1, wherein the bias circuit comprises a diode varactor.

10. The power amplifier circuit of claim 1, wherein the bias circuit comprises a field effect transistor (FET) varactor.

11. The power amplifier circuit of claim 1, wherein the APD circuit provides an adjustment signal to the bias circuit.

12. A mobile communication device comprising, a transmit circuit comprising:
a power management circuit configured to:
receive a signal from a baseband processor relating to a power level for a transmit signal; and
output a supply voltage signal;
a power amplifier circuit
comprising:
an amplifier stage configured to:
receive the transmit signal and amplify the transmit signal; and
receive the supply voltage signal;
a bias circuit coupled to the amplifier stage and configured to provide a bias signal to the amplifier stage based at least in part on the supply voltage signal; and
an analog predistortion (APD) circuit configured to predistort the transmit signal based at least in part on the supply voltage signal.

13. The mobile communication device of claim 12, wherein the power management circuit comprises an average power tracking (APT) circuit.

14. The mobile communication device of claim 12, wherein the power management circuit comprises an envelope tracking (ET) circuit.

15. The mobile communication device of claim 12, wherein the power amplifier circuit further comprises a voltage supply correction circuit coupled to the power management circuit and configured to receive the supply voltage signal and send control signals to the bias circuit and the APD circuit based on the supply voltage signal.

16. The mobile communication device of claim 12, wherein the power management circuit is further configured to provide a predistorted supply voltage signal to the power amplifier circuit.

17. The mobile communication device of claim 16, wherein the power amplifier circuit further comprises a voltage supply correction circuit coupled to the power management circuit and configured to receive the predistorted supply voltage signal.

18. The mobile communication device of claim 12, wherein the power management circuit is configured to receive the signal during a cyclic prefix (CP) time before a symbol in the transmit signal.

19. A method of managing predistortion in a transmit circuit, comprising:
receiving, at an amplifier stage, a transmit signal;
amplifying the transmit signal;
receiving a signal containing information relating to a supply voltage being provided to the amplifier stage;
providing a bias signal to the amplifier stage based at least in part on the signal; and
predistorting the transmit signal with an analog predistortion (APD) circuit based at least in part on the signal.

20. The method of claim 19, wherein amplifying the transmit signal comprises imposing a distortion on the transmit signal that is offset at least in part by the predistorting.
